(19) United States
(12) Patent Application Publication
(10) Pub. No.: US 2025/0364435 A1
(43) Pub. Date: Nov. 27, 2025

(54) WAFER WARPAGE REDUCTION

(71) Applicant: Taiwan Semiconductor Manufacturing Company, Ltd., Hsinchu (TW)

(72) Inventor: Yung-Shih Cheng, Hsinchu City (TW)

(21) Appl. No.: 18/674,345

(22) Filed: May 24, 2024

(51) Int. Cl. H01L 23/00

(52) U.S. Cl. CPC H01L 23/562; H01L 24/32; H01L 24/83; H01L 2224/32225; H01L 2224/83896

(57) ABSTRACT

Methods for reducing wafer warpage are provided. A method according to the present disclosure includes depositing a compressive dielectric layer over a device wafer, the device wafer including a first substrate, a device layer on the first substrate, and a first interconnect structure over the device layer, depositing a first bonding layer on the compressive dielectric layer, depositing a second bonding layer on a second substrate, and bonding the second substrate and the device wafer by bonding the first bonding layer and the second bonding layer. The first bonding layer and the second bonding layer include a dielectric material having a thermal conductivity greater than a thermal conductivity of silicon oxide.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the scaling down of IC devices continues, routing for IC devices may be achieved through not only a frontside interconnect structure but also a backside interconnect structure. Formation of the backside interconnect structure may involve bonding a device wafer to a carrier substrate through a bonding layer and flipping the device wafer over. The bonding layer affects heat dissipation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a device die, according to one or more aspects of the present disclosure.

FIGS. 2-14 illustrate fragmentary cross-sectional views of a device wafer and/or a carrier substrate during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. For avoidance of doubts, the X, Y and Z directions in figures of the present disclosure are perpendicular to one another. Throughout the present disclosure, like reference numerals denote like features, unless otherwise excepted.

For semiconductor devices fabricated on a bulk semiconductor substrate, the bulk semiconductor substrate may serve as a heat sink to pull away heat generated by the semiconductor devices and conduct heat into a heat sink. In some technologies where the semiconductor substrate is thinned or substantially removed to implement a backside interconnect structure, a carrier substrate is bonded to a frontside interconnect structure by way of a bonding layer. When the bonding layer includes a less-than-ideal thermal conductor, heat from the semiconductor devices cannot be effectively dissipated. The semiconductor devices may experience degradation due to self-heating and substantial warpage may be induced.

The present disclosure provides a method for reducing warpage of a device wafer and improving thermal conduction path to prevent damages to semiconductor devices on the device wafer. In one embodiment, a compressive dielectric layer is deposited over a device wafer to exert a compressive stress on the device wafer. The device wafer includes a first substrate, a device layer on the first substrate, and a first interconnect structure over the device layer. A first bonding layer is deposited on the compressive dielectric layer and a second bonding layer is deposited on a second substrate. The second substrate is bonded to the device wafer by bonding the first bonding layer and the second bonding layer. The first substrate is thinned and a second interconnect structure is disposed over the device layer. The compressive dielectric layer may include silicon nitride. The first bonding layer and the second bonding layer may include a dielectric material having a thermal conductivity greater than a thermal conductivity of silicon oxide (i.e., about 1 W/mk).

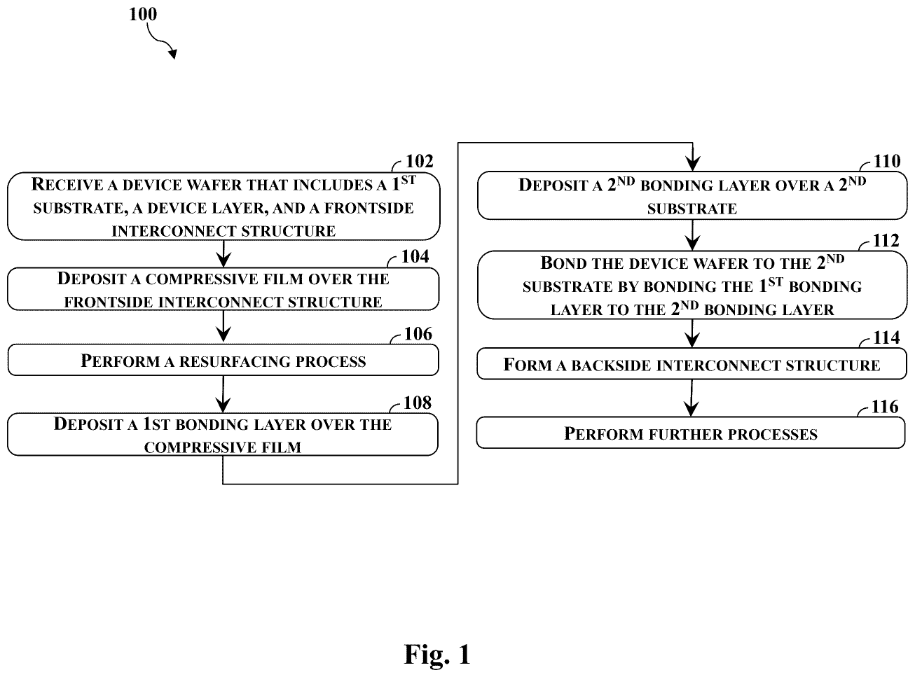

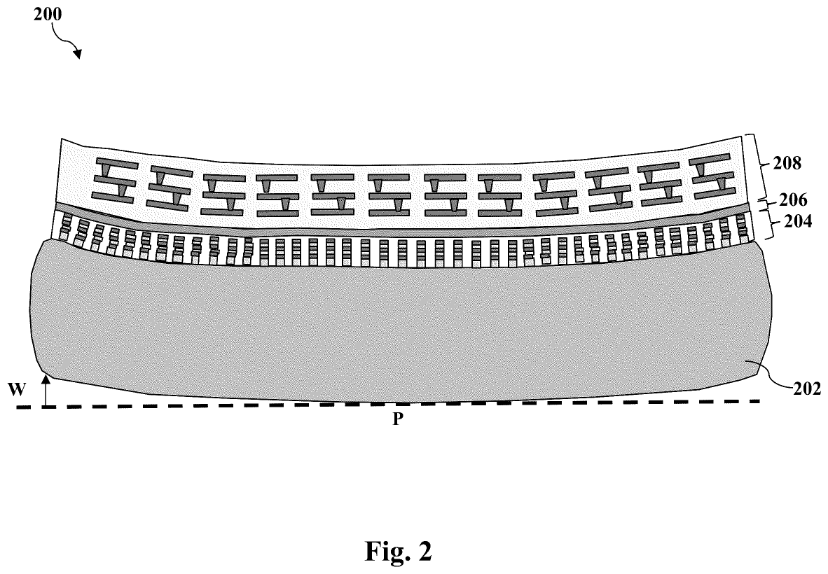

The various aspects of the present disclosure will now be described in more detail with reference to the figures. In that regard, FIG. 1 is a flowchart illustrating method 100 of forming a device die according to embodiments of the present disclosure. Method 100 is merely an example and is not intended to limit the present disclosure to what is explicitly illustrated in method 100. Additional steps may be provided before, during and after the method 100, and some steps described can be replaced, eliminated, or moved around for additional embodiments of the method. Not all steps are described herein in detail for reasons of simplicity. Method 100 is described below in conjunction with FIGS. 2-14, which are fragmentary cross-sectional views of a device wafer and/or a carrier substrate at different stages of fabrication according to embodiments of method 100. Throughout the present disclosure, like reference numerals denote like features, unless otherwise excepted.

Referring to FIGS. 1 and 2, method 100 includes a block 102 where a device wafer 200 is received. In some embodiments represented in FIG. 2, the device wafer 200 includes a first substrate 202, a device layer 204 fabricated on the first substrate 202, a contact layer 206 over the device layer 204, and a frontside interconnect structure 208 over the contact layer 206. In semiconductor technology, the device layer 204 is manufactured before the contact layer 206 and the frontside interconnect structure 208 and is considered front-end-of-line (FEOL) structures. The contact layer 206 is fabricated after the device layer and functions to connect the devices in the device layer 204 to the frontside interconnect structure. The contact layer 206 may be referred to as middle-end-of-line (MEOL) structures. The frontside interconnect structure 208 is fabricated after the device layer 204 and the contact layer 206 and may be referred to as back-end-of-line (BEOL) structures.

In some embodiments, the first substrate 202 substrate may be a silicon (Si) substrate. In some other embodiments, the first substrate 202 includes elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, the first substrate 202 includes one or more group III-V materials, one or more group II-VI materials, or combinations thereof. In still some instances, the first substrate 202 is a semiconductor-on-insulator substrate, such as a silicon-on-insulator (SOI) substrate, a silicon germanium-on-insulator (SGOI) substrate, or a germanium-on-insulator (GeOI) substrate. The first substrate 202 may include n-type and p-type doped well regions. An n-type doped region includes an n-type dopant, such as phosphorus (P) or arsenic (As). A p-type doped region includes a p-type dopant, such as boron (B). In some instances, the first substrate 202 may have a thickness between about 750 μm and about 800 μm.

The device layer 204 may include planar devices or multi-gate devices. A planar device refers to a device having a gate structure engaging one side of a channel region. As integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. Due to this configuration, a GAA transistor may also be referred to as a surrounding-gate transistor (SGT) or a multi-bridge-channel (MBC) transistor. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor. In the depicted embodiments, the device layer 204 includes multi-gate transistors, such as GAA transistors. Generally, planar devices tend to have larger feature dimensions and usually do not need a backside interconnect structure for routing.

In the illustrated embodiment, the transistors in the device layer 204 have a GAA construction. Each of the transistors includes a plurality of channel members that are vertically stacked one over another over the first substrate 202. The plurality of channel members extend between two source/drain features. A gate structure wraps around each of the channel members. The gate structure is spaced apart from the two source/drain features by a plurality of inner spacer features. The plurality of inner spacer features vertically interleave the plurality of channel members. A top portion of the gate structure is lined with top gate spacers. In some embodiments, the plurality of channel members include silicon (Si). The gate structure includes a gate dielectric layer and a gate electrode layer over the gate dielectric layer. In some embodiments, the gate dielectric layer includes an interfacial layer to interface the channel members and a high-K gate dielectric layer over the interfacial layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed using ALD, PVD, CVD, e-beam evaporation, or other suitable process.

The source/drain features of the transistors in the device layer 204 may include silicon (Si) doped with an n-type dopant, such as phosphorus (P) or arsenic (As) or silicon germanium (SiGe) doped with a p-type dopant, such as boron (B) or boron difluoride (BF₂). The inner spacer features may include silicon nitride, silicon oxycarbonitride, silicon oxynitride, or silicon oxycarbide. The top gate spacers define the gate trench in a gate replacement process and may include silicon nitride, silicon oxycarbonitride, silicon oxynitride, or silicon oxycarbide.

The MEOL contact layer 206 may include contacts to gate structures and source/drain features of the devices in the device layer 204. Contacts to gate structures (or gate contacts) may include tungsten (W), ruthenium (Ru), copper (Cu), or molybdenum (Mo) and couple gate structures to the frontside interconnect structure 208. Contacts to source/drain features (or source/drain contacts) may include cobalt (Co), nickel (Ni), or copper (Cu) and couple source/drain features to the frontside interconnect structure 208. The gate contacts and the source/drain contacts in the contact layer 206 extend through at least one etch stop layer (ESL) and at least one interlayer dielectric (ILD) layer. The at least one etch stop layer (ESL) may include silicon nitride, silicon oxynitride, or aluminum nitride. The at least one ILD layer may include silicon oxide or a dielectric material having a low dielectric constant. The gate contacts and the source/drain contacts may be spaced apart from the at least one ESL and the at least one ILD layer by a barrier layer. The barrier layer may include titanium nitride or tantalum nitride.

In some embodiments, the frontside interconnect structure 208 may include 8 to 25 metallization layers. Each of the metallization layers includes conductive lines and contact vias embedded in an intermetal dielectric (IMD) layer. The IMD layer may include materials such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials. The conductive lines and contact vias may include copper (Cu), titanium nitride (TiN), tungsten (W), or ruthenium (Ru). The frontside interconnect structure 208 functionally connect transistors in the device layer 204 by way of the contact features in the contact layer 206. In some embodiments not explicitly shown in the figures, active and passive devices may be included in the frontside interconnect structure 208. Examples of such active and passive devices may include, for example metal-insulator-metal (MIM) capacitors, radio frequency (RF) antennas, deep trench capacitors, memory devices, or transistors.

In some embodiments, residual stress in dielectric layers in the device layer 204, the contact layer 206 and the frontside interconnect structure 208 may cause the device wafer 200 to warp. Generally, the warpage of the device wafer 200 depends on the number of metallization layers in the interconnect structure 208. For example, an interconnect structure 208 with 20 metallization layers may cause the device wafer 200 to warp about twice as much as a device wafer having an interconnect structure with 10 or less metallization layers. Warpage W may be measured as a difference between an edge of the device wafer 200 and a reference plane P. In some instances, after the frontside interconnect structure 208 is formed and a top surface of the device wafer 200 is planarized, the device wafer 200 may include a warpage W between about 100 μm and about 200 μm.

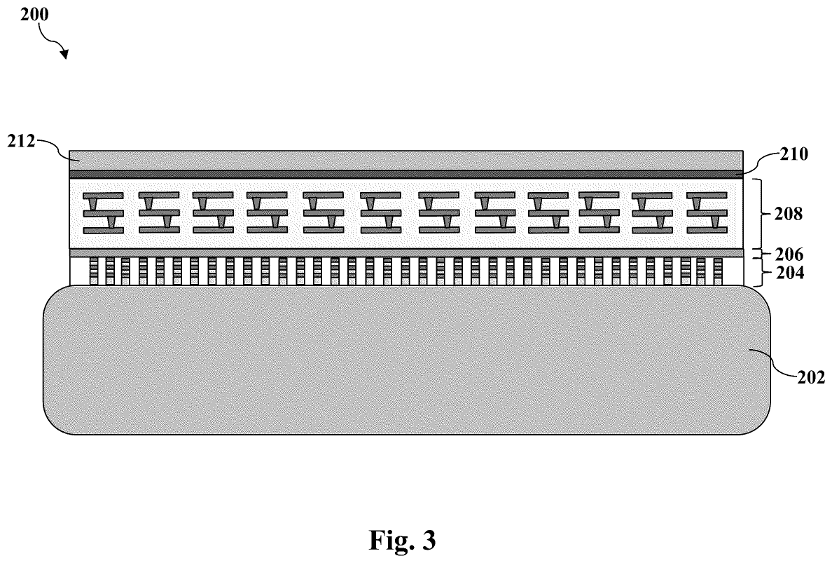

Referring to FIGS. 1 and 3, method 100 includes a block 104 where a compressive film 212 is deposited over the frontside interconnect structure 208. The compressive film 212 includes a dielectric material and is deposited in a way such that it exerts compressive stress on the device wafer 200 to counteract the warpage in the device wafer 200. In some embodiments, the compressive film 212 includes silicon nitride and is deposited using chemical vapor deposition (CVD) or plasma enhanced CVD (PECVD). The compressive film 212 may exert a compressive stress between about 1.75 Gpa and about 2.4 Gpa, which is an order of magnitude greater than a compressive stress of a compressive film made of silicon oxide. That is, adoption of the compressive film 212 of the present disclosure may greatly reduce the thickness of the compressive film. To ensure that the compressive film 212 exerts sufficient compressive stress on the device wafer 200 to unwarp it, the compressive film 212 may have a thickness between about 50 nm and about 100 nm. This range is not trivial. When the thickness of the compressive film 212 is smaller than 50 nm, the compressive film 212 may not be thick enough to completely unwarp the device wafer 200. When the thickness of the compressive film 212 is greater than 100 nm, the compressive film 212 may warp the device wafer 200 and the added thickness may hinder heat dissipation. The compressive film 212 has a thermal conductivity greater than that of silicon oxide. When the compressive film 212 includes silicon nitride, it may have a Kappa value (W/mk) between 2 and 5 while a Kappa value of silicon oxide is about 1.

In some embodiments represented in the figures, an etch stop layer 210 may be deposited over the frontside interconnect structure 208 before the compressive film 212 is deposited. To perform its etch stop functions, the etch stop layer 210 is formed of a dielectric material different from the intermetal dielectric (IMD) layer in the frontside interconnect structure 208 or the compressive film 212. In some embodiments, the etch stop layer 210 includes silicon carbonitride. The etch stop layer 210 may be deposited using CVD or PECVD. In some embodiments when through substrate vias are formed through a carrier wafer (to be describe below) to electrically connect to the interconnect structure 208, the etch stop layer 210 may serve as an etch stop layer for the formation of the through substrate vias.

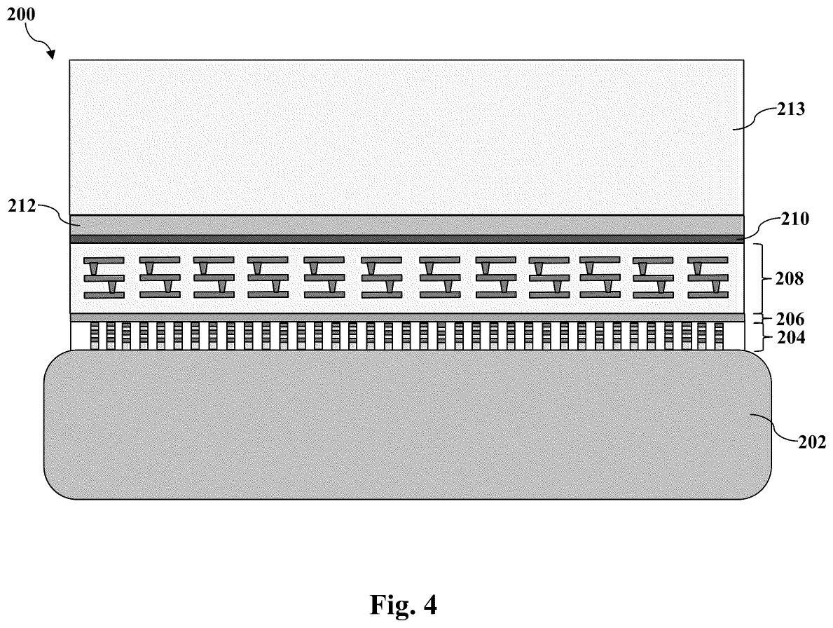

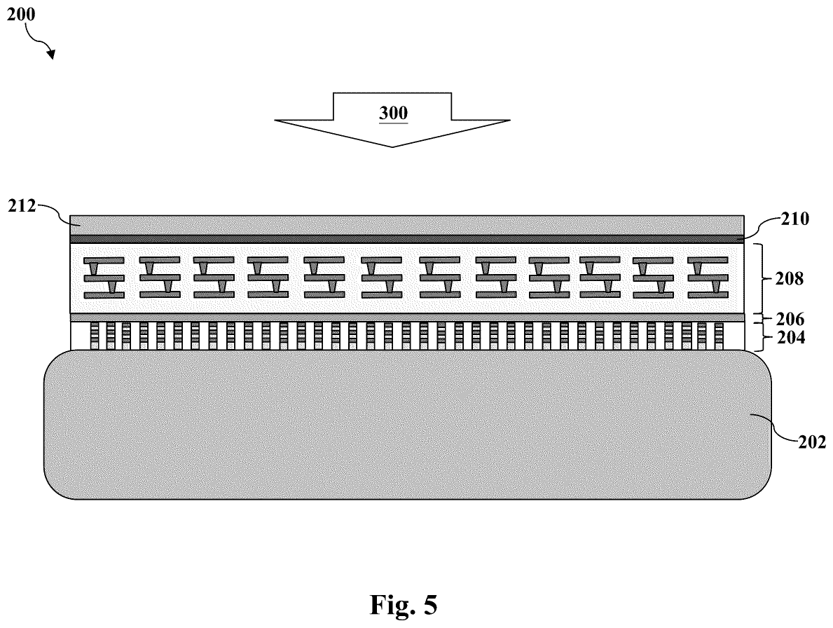

Referring to FIGS. 1, 4 and 5, method 100 includes a block 106 where a resurfacing process is performed to the device wafer 200. As described above with respect to block 104, the compressive film 212 exerts a compressive stress on the device wafer 200 to unwarp it. While the compressive film 212 may address the warpage of the device wafer 200, a top surface of the compressive film 212 may still have an average roughness (Ra) between 500 Å and about 1500 Å, which is not suitable for the subsequent bonding process. The resurfacing process at block 106 is aimed to reduce the surface roughness. Referring to FIG. 4, a resurfacing dielectric layer 213 is deposited over the compressive film 212 by CVD. In some embodiments, the resurfacing dielectric layer 213 may include silicon oxide. In one embodiment, the deposition of the resurfacing dielectric layer 213 may include use of tetraethyl orthosilicate (TEOS) and the resurfacing dielectric layer 213 may be referred to as a TEOS oxide layer. In order to remove or reduce the surface roughness that is in the range between 500 Å and about 1500 Å, the resurfacing dielectric layer 213 may have a thickness between about 5000 Å and about 15000 Å, which is about 10 times of the average surface roughness of the compressive film 212. After the deposition of the resurfacing dielectric layer 213, a planarization process 300 is performed to the resurfacing dielectric layer 213 to remove about 5000 Å and about 15000 Å of material, as shown in FIG. 5. While FIG. 5 shows that all of the resurfacing dielectric layer 213 has been removed, trace of the resurfacing dielectric layer 213 remains on the compressive film 212 to provide a surface with a reduced average surface roughness between about 50 Å and about 100 Å.

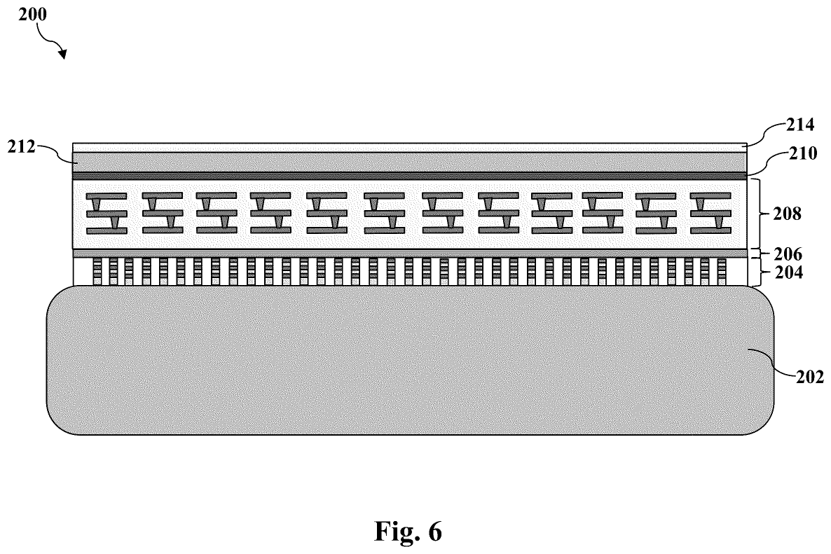

Referring to FIGS. 1 and 6, method 100 includes a block 108 where the first bonding layer 214 is deposited over the compressive film 212. As will be described further below, the first bonding layer 214 is configured to be bonded to a second bonding layer 216 in a subsequent direct bonding process. Additionally, the first bonding layer 214 and the second bonding layer 216 are in the heat conduction path to dissipate heat from the device layer 204. For these reasons, it is desirable for the first bonding layer 214 to be formed of a material that is compatible with a direct bonding process and does not hinder heat conduction. In some embodiments, the first bonding layer 214 includes metal-like materials, such as titanium oxide or aluminum nitride, and may have a thickness between 50 nm and about 25 μm. In one embodiment, the first bonding layer 214 includes titanium oxide. In some implementations, the first bonding layer 214 is deposited using atomic layer deposition (ALD), CVD or metalorganic CVD (MOCVD). Both titanium oxide and aluminum nitride are compatible with the direct bonding process and have a thermal conductivity (Kappa) greater than that of silicon oxide. In some instances, the first bonding layer 214 may have a Kappa value (W/mk) between 10 and 100 while a Kappa value of silicon oxide is about 1.

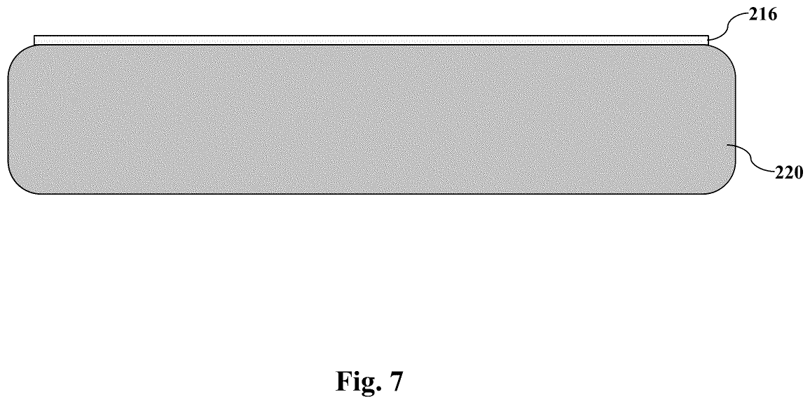

Referring to FIGS. 1 and 7, method 100 includes a block 110 where a second bonding layer 216 is deposited over a second substrate 220. As will be described in more details below, method 100 includes operations to bond the second substrate 220 to the device wafer 200 to provide mechanical strength while the first substrate 202 is thinned and partially removed. To achieve that, the second bonding layer 216 is deposited on the second substrate 220 to interface the first bonding layer 214 in a direct bonding process. In some embodiments, the second substrate 220 includes elementary semiconductor, such as silicon (Si) or germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In one embodiment, the second substrate 220 may include silicon (Si). In some alternative embodiments, the second substrate 220 may include glass. The bonding of the second substrate 220 allows the device wafer 200 to be flipped over for further processing and the second substrate 220 provides mechanical strength to the device wafer 200. For these reasons, the second substrate 220 may also be referred to as a carrier substrate 220 or a carrier wafer 220. In some instances, the second substrate 220 may have a thickness between about 750 μm and about 800 μm.

The second bonding layer 216 is configured to be directly bonded to the first bonding layer 214 in a subsequent process. Like the first bonding layer 214, the second bonding layer 216 is in the heat conduction path to dissipate heat from the device layer 204. For these reasons, it is desirable for the second bonding layer 216 to be formed of a material that is compatible with a direct bonding process and does not hinder heat conduction. In some embodiments, the second bonding layer 216 includes metal-like materials, such as titanium oxide or aluminum nitride, and may have a thickness between about 50 nm and about 25 μm. In one embodiment, the second bonding layer 216 includes titanium oxide. In some implementations, the second bonding layer 216 is deposited using atomic layer deposition (ALD), CVD or metalorganic CVD (MOCVD). Both titanium oxide and aluminum nitride are compatible with the direct bonding process and have a thermal conductivity (Kappa) greater than that of silicon oxide. In some instances, the second bonding layer 216 may have a Kappa value (W/mk) between 10 and 100 while a Kappa value of silicon oxide is about 1.

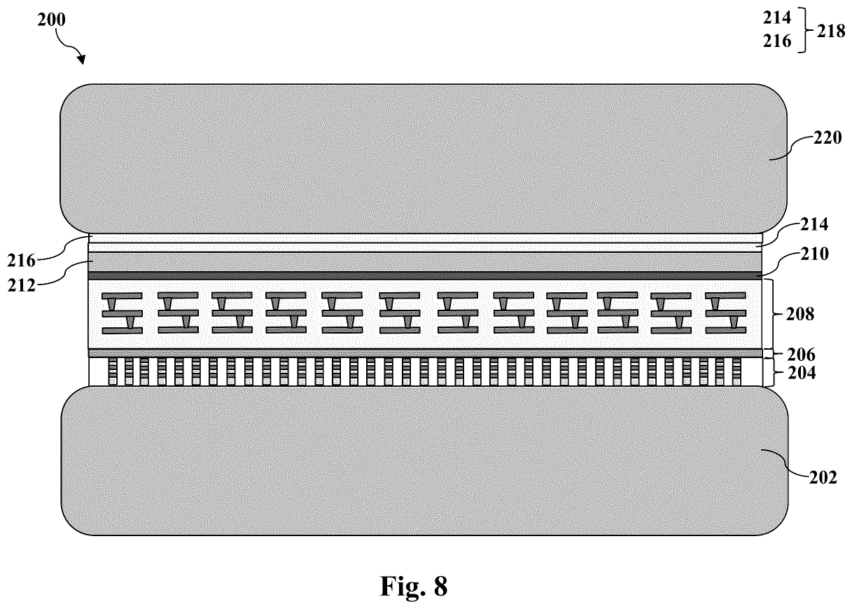

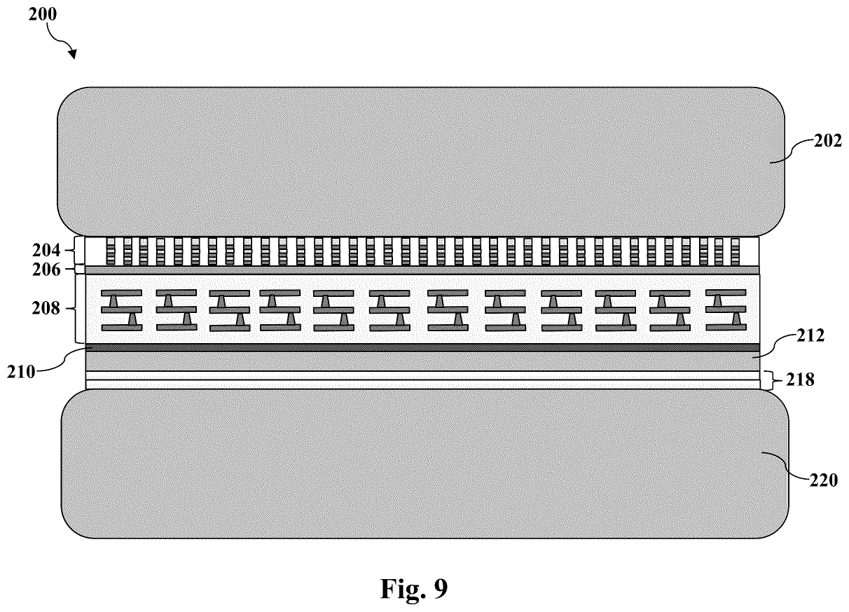

Referring to FIGS. 1, 8 and 9, method 100 includes a block 112 where the device wafer 200 is bonded to the second substrate 220 by bonding the first bonding layer 214 to the second bonding layer 216. To bond the first bonding layer 214 and the second bonding layer 216, surfaces of the first bonding layer 214 and the second bonding layer 216 are first activated with a plasma treatment. In some embodiments, the plasma treatment may include use of plasma of oxygen (O₂), nitrogen (N₂), or a combination thereof. After the plasma activation, the first bonding layer 214 and the second bonding layer 216 are pressed together, as shown in FIG. 8. An anneal process is then performed to form covalent bonds at the interface between the first bonding layer 214 and the second bonding layer 216. The plasma treatment activation helps lower the annealing temperature in the anneal process, thereby reducing thermal damages to the device wafer 200. After operations at block 110, the first bonding layer 214 and the second bonding layer 216 may be collectively referred to as bonding layers 218. As shown in FIG. 9, the device wafer 200, along with the second substrate 220 bonded thereto, is flipped upside down for subsequent process steps.

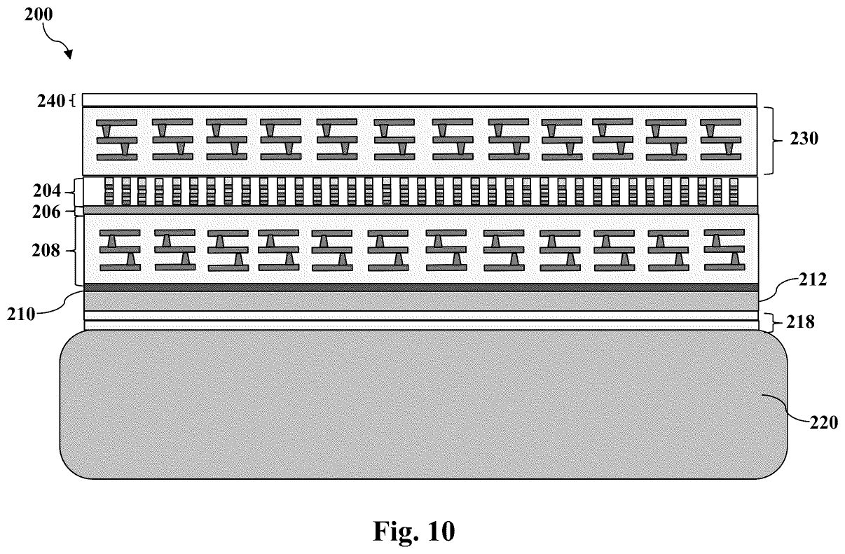

Referring to FIGS. 1 and 10, method 100 includes a block 114 where a backside interconnect structure 230 is formed. Operations at block 114 may include thinning of the first substrate 202, formation of backside contacts, and formation of the backside interconnect structure 230. The thinning of the first substrate 202 includes a mechanical grinding process and a chemical mechanical polishing (CMP). A substantial amount of substrate material may be first removed from the first substrate 202 during a mechanical grinding process. Afterwards, a CMP process is performed further thin down the first substrate 202 and provide a planar backside surface. Depending on presence of self-alignment features, backside contact openings may be formed over the backside surface to expose source features, drain features, or gate structures using photolithography techniques or selective etching. A dielectric liner and a barrier layer may be deposited over the backside contact openings. Depending on whether the contacts are coupled to a source/drain feature, a silicide layer may be formed in the contact opening to interface the source/drain feature. Then a metal fill layer is deposited over the contact openings to form the backside contact features. The dielectric liner may include silicon nitride. The barrier layer in the backside contacts may include titanium nitride or tantalum nitride. The metal fill layer may include tungsten (W), cobalt (Co), molybdenum (Mo), ruthenium (Ru), copper (Cu), or aluminum (Al). The silicide feature may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

The backside interconnect structure 230 is then formed to couple to the backside contacts. The backside interconnect structure 230 shown in FIG. 10 may include 3 to 12 metal layers. Each of the metal layers includes conductive lines embedded in an intermetal dielectric (IMD) layer. The backside interconnect structure 230 also includes contact vias that vertically interconnect conductive lines in different metal layers. The IMD layer may include materials such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials. The conductive lines and contact vias may include aluminum (Al), copper (Cu), titanium nitride (TiN), tungsten (W), or ruthenium (Ru).

A redistribution layer (RDL) 240 may be formed over the backside interconnect structure 230. The RDL 240 is an extra metal layer that redirects signals from contact pads of the backside interconnect structure to other locations for better access. Because an RDL structure is usually on top of a die and is formed at the end of the BEOL process, it usually is home of test pads or probing pads, such as wafer acceptance test (WAT) pads. By probing the WAT pads, process control monitoring data is generated to improve yield and reduce defects. In additional to WAT pads, the RDL 240 also includes contact pads configured to couple to bump features.

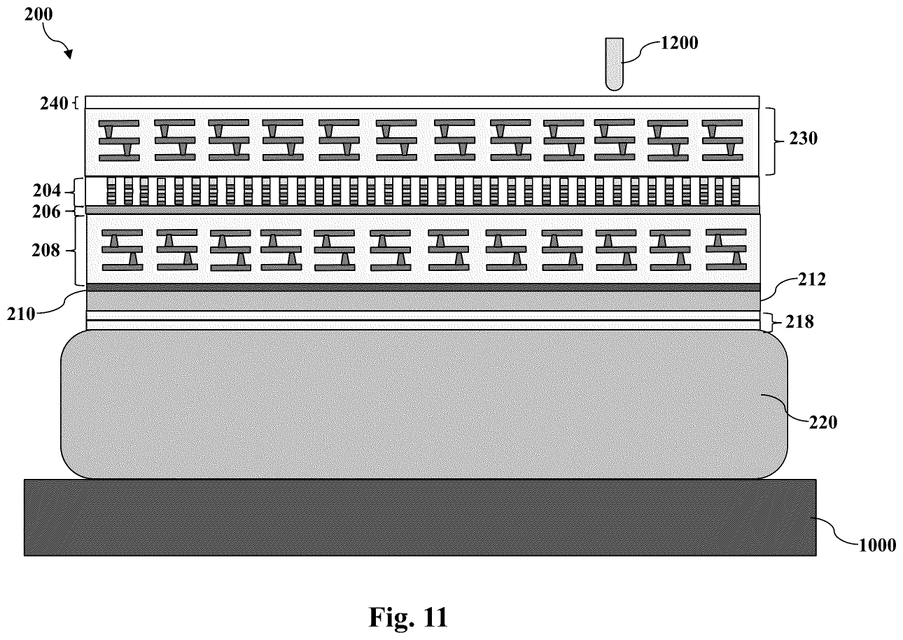

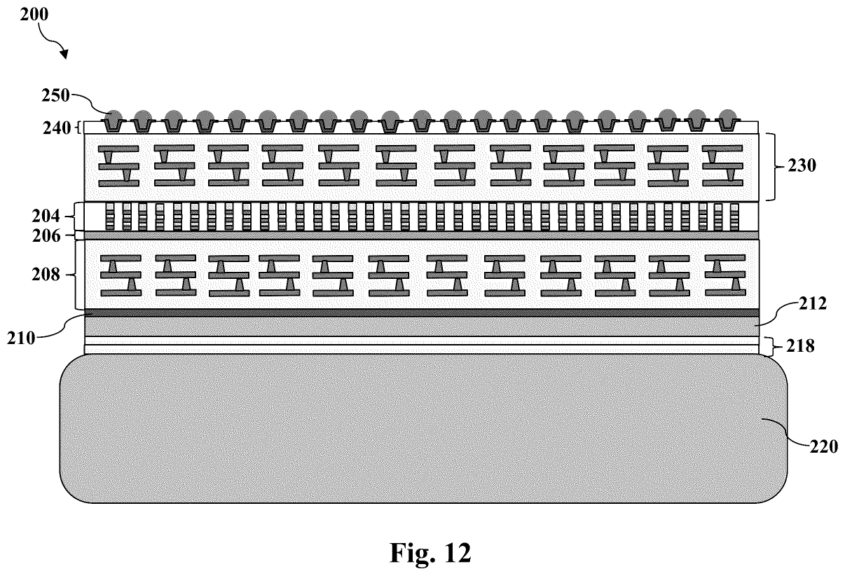

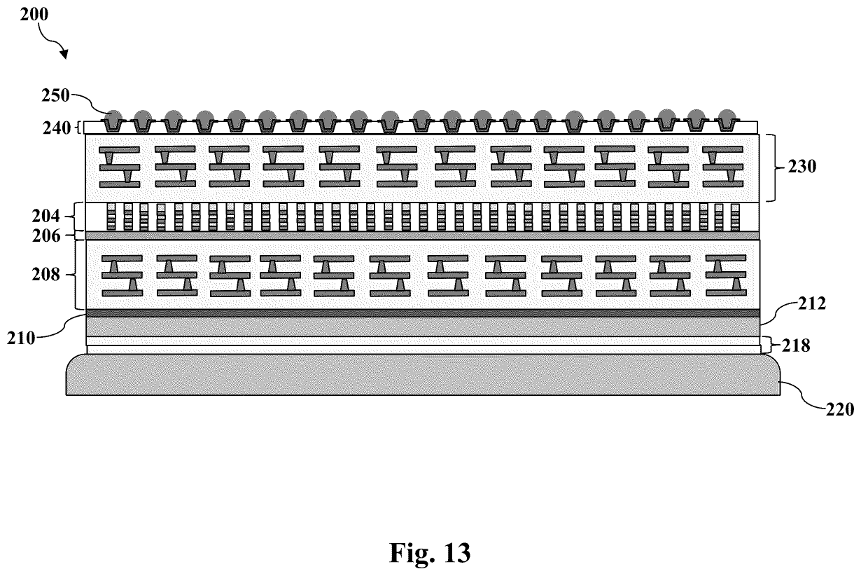

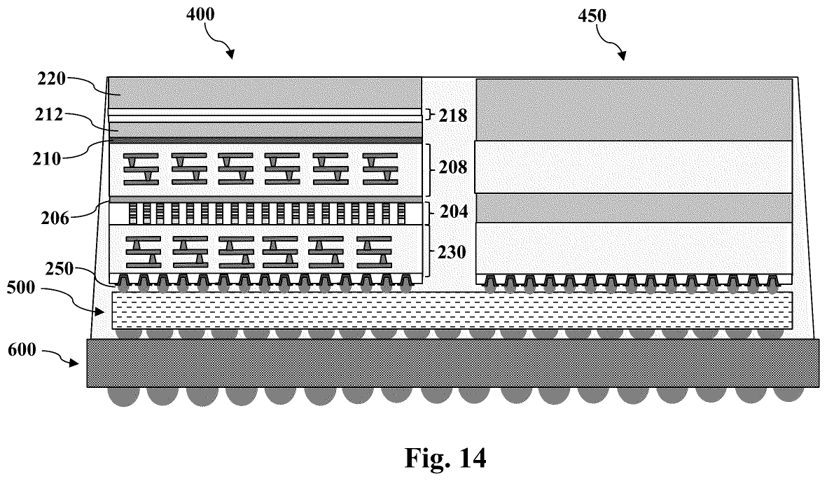

Referring to FIGS. 1, 11, 12, 13, and 14, method 100 includes a block 116 where further processes are performed. Such further processes may include testing (shown in FIG. 11), formation of a redistribution layer 240 and bump features 250 (shown in FIG. 12), thinning of the carrier substrate 220 (shown in FIG. 13), and singulation (shown in FIG. 14). Referring to FIG. 11, the device wafer 200 is mounted on a wafer chuck 1000. In some embodiments, the wafer chuck 1000 is a WAT chuck 1000. To perform a wafer acceptance test, a probe 1200 is caused to contact the WAT pads over the device wafer 200. In some embodiments, the probe 1200 is one of many probes in a probe card. By having a physical and electrical contact between the probe 1200 and a WAT pad, an electronic test system may perform an automated integrated circuit testing. The probe 1200 may also be referred to as an electrical connector or a pin. After the device wafer 200 is tested, bump features 250 are formed over the device wafer 200, as illustrated in FIG. 12.

The RDL 240 includes a passivation layer covering a top RDL metal layer. To form the bump features 250, an opening is formed in the passivation layer to expose a portion of the top RDL metal layer. An under-bump-metallization (UBM) feature is formed over the exposed portion of the top RDL metal layer. Then a bump feature 250 is formed over the UBM feature. The RDL metal layer may include copper (Cu). The UBM layer may include a barrier layer and a seed layer. The barrier layer may include titanium nitride or tantalum nitride. The seed layer may include copper (Cu), silver (Ag), chromium (Cr), tin (Sn), gold (Au), and combinations thereof. After the formation of the UBM layer, a bump feature 250 is formed on the UBM layer. The bump features 250 may include Pb-Sn, InSb, tin, silver, copper, or a combination thereof.

After the bump features 250 are formed, the second substrate 220 is thinned using a mechanical grinding, a chemical mechanical polishing (CMP), or a combination thereof. In some instance, the second substrate 220 may be thinned to about 40 μm and about 760 μm, as shown in FIG. 13. When no through substrate vias are formed through the second substrate 220, the second substrate 220 may only be thinned slightly to provide mechanical support and serve as a heat sink. When the packaging or die stacking requires formation of through substrate vias through the second substrate 220, the second substrate 220 may be thinned down to a thickness between 40 μm and about 60 μm.

After the thinning of the second substrate 220, the device wafer 200 may undergo a singulation process where individual device dies 400 are singulated. In some embodiments, the singulation of the device dies may include a laser cutting process. A device die 400 is illustrated in FIG. 14. The device die 400 includes a plurality of the bump features 250 to interface a package structure or a package substrate. The backside interconnect structure 230 is disposed over the bump features 250. The device layer 204 is disposed over the backside interconnect structure 230. By way of the contact layer 206, transistors in the device layer 204 are electrically coupled to the frontside interconnect structure 208. Both the frontside interconnect structure 208 and the backside interconnect structure 230 provide signal routing for the transistors in the device layer 204. The etch stop layer 210 is deposited over the frontside interconnect structure 208. The compressive film 212 is disposed over the etch stop layer 210. The bonding layers 218 are disposed over the compressive film 212. The second substrate 220 is disposed over the bonding layers 218 to provide mechanical strength to the device die 400. The device die 400 may be mounted over a package structure or a package substrate by way of the bump features 250. In some embodiments represented in FIG. 14, the device die 400 and another device die 450 are mounted over an interposer 500, which is mounted on in a package substrate 600. In the depicted implementation, the bump features 250 are surrounded by an underfill and the device die 400, device die 450, and the interposer 400 are surrounded by molding materials.

In one exemplary aspect, the present disclosure is directed to a semiconductor device. The semiconductor device includes a substrate, a bonding layer over the substrate, a compressive dielectric layer over the bonding layer, a first interconnect structure over the compressive dielectric layer, a device layer over the first interconnect structure, a second interconnect structure over the device layer. A Kappa value of the bonding layer is between about 10 and about 100.

In some embodiments, the bonding layer includes titanium oxide or aluminum nitride. In some embodiments, the compressive dielectric layer includes silicon nitride. In some implementations, the semiconductor device further includes an etch stop layer between the compressive dielectric layer and the first interconnect structure. The etch stop layer includes silicon carbonitride. In some embodiments, the bonding layer includes a thickness between about 50 nm and about 25 μm. In some implementations, the compressive dielectric layer includes a thickness between about 50 nm and about 100 m.

In another exemplary aspect, the present disclosure is directed to a method. The method includes depositing a compressive dielectric layer over a device wafer, the device wafer including a first substrate, a device layer on the first substrate, and a first interconnect structure over the device layer, depositing a first bonding layer on the compressive dielectric layer, depositing a second bonding layer on a second substrate, and bonding the second substrate and the device wafer by bonding the first bonding layer and the second bonding layer. The first bonding layer and the second bonding layer include a dielectric material having a thermal conductivity greater than a thermal conductivity of silicon oxide.

In some embodiments, the first bonding layer and the second bonding layer include titanium oxide or aluminum nitride. In some embodiments, the compressive dielectric layer includes silicon nitride. In some implementations, each of the first bonding layer and the second bonding layer has a thickness between about 50 nm and about 25 μm. In some embodiments, the compressive dielectric layer has a thickness between about 50 nm and about 100 nm. The compressive dielectric layer exerts a compressive stress on the device wafer. In some embodiments, the device layer includes a plurality of multi-gate transistors. In some embodiments, the method further includes before the depositing of the compressive dielectric layer over the device wafer, depositing an etch stop layer over the device wafer. After the depositing of the compressive dielectric layer, the etch stop layer is sandwiched between the compressive dielectric layer and the device wafer. In some embodiments, the etch stop layer includes silicon carbonitride. In some embodiments, the method further includes after the bonding of the second substrate and the device wafer, thinning the first substrate; and forming a second interconnect structure over the device layer.

In yet another exemplary aspect, the present disclosure is directed to a method. The method includes forming a device layer over a first substrate, forming a frontside interconnect structure over the device layer, depositing a compressive dielectric layer over the frontside interconnect structure, depositing a first bonding layer on the compressive dielectric layer, depositing a second bonding layer on a second substrate, bonding the second substrate and the first substrate by bonding the first bonding layer and the second bonding layer, thinning the first substrate, and after the thinning of the first substrate, forming a backside interconnect structure over the device layer. The first bonding layer and the second bonding layer include titanium oxide or aluminum nitride.

In some embodiments, the compressive dielectric layer includes silicon nitride. In some implementations, a thickness of the compressive dielectric layer is greater than a thickness of the first bonding layer or a thickness of the second bonding layer. In some instances, the method further includes before the depositing of the compressive dielectric layer over the frontside interconnect structure, depositing an etch stop layer over the frontside interconnect structure. The etch stop layer includes silicon carbonitride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a bonding layer over the substrate;
a compressive dielectric layer over the bonding layer;
a first interconnect structure over the compressive dielectric layer;
a device layer over the first interconnect structure; and
a second interconnect structure over the device layer,
wherein a Kappa value of the bonding layer is between about 10 and about 100.

2. The semiconductor device of claim 1, wherein the bonding layer comprises titanium oxide or aluminum nitride.

3. The semiconductor device of claim 1, wherein the compressive dielectric layer comprises silicon nitride.

4. The semiconductor device of claim 1, further comprising:
an etch stop layer between the compressive dielectric layer and the first interconnect structure,
wherein the etch stop layer comprises silicon carbonitride.

5. The semiconductor device of claim 1, wherein the bonding layer comprises a thickness between about 50 nm and about 25 μm.

6. The semiconductor device of claim 1, wherein the compressive dielectric layer comprises a thickness between about 50 nm and about 100 nm.

7. A method, comprising:
depositing a compressive dielectric layer over a device wafer, the device wafer including a first substrate, a device layer on the first substrate, and a first interconnect structure over the device layer;
depositing a first bonding layer on the compressive dielectric layer;
depositing a second bonding layer on a second substrate; and
bonding the second substrate and the device wafer by bonding the first bonding layer and the second bonding layer,
wherein the first bonding layer and the second bonding layer comprise a dielectric material having a thermal conductivity greater than a thermal conductivity of silicon oxide.

8. The method of claim 7, wherein the first bonding layer and the second bonding layer comprise titanium oxide or aluminum nitride.

9. The method of claim 7, wherein the compressive dielectric layer comprises silicon nitride.

10. The method of claim 7, wherein each of the first bonding layer and the second bonding layer comprises a thickness between about 50 nm and about 25 μm.

11. The method of claim 7, wherein the compressive dielectric layer comprises a thickness between about 50 nm and about 100 nm.

12. The method of claim 7, wherein the compressive dielectric layer exerts a compressive stress on the device wafer.

13. The method of claim 7, wherein the device layer comprises a plurality of multi-gate transistors.

14. The method of claim 7, further comprising:
before the depositing of the compressive dielectric layer over the device wafer, depositing an etch stop layer over the device wafer,
wherein, after the depositing of the compressive dielectric layer, the etch stop layer is sandwiched between the compressive dielectric layer and the device wafer.

15. The method of claim 14, wherein the etch stop layer comprises silicon carbonitride.

16. The method of claim 7, further comprising:
after the bonding of the second substrate and the device wafer, thinning the first substrate; and
forming a second interconnect structure over the device layer.

17. A method, comprising:
forming a device layer over a first substrate;
forming a frontside interconnect structure over the device layer;
depositing a compressive dielectric layer over the frontside interconnect structure;
depositing a first bonding layer on the compressive dielectric layer;
depositing a second bonding layer on a second substrate;
bonding the second substrate and the first substrate by bonding the first bonding layer and the second bonding layer;
thinning the first substrate; and
after the thinning of the first substrate, forming a backside interconnect structure over the device layer,
wherein the first bonding layer and the second bonding layer comprise titanium oxide or aluminum nitride.

18. The method of claim 17, wherein the compressive dielectric layer comprises silicon nitride.

19. The method of claim 17, wherein a thickness of the compressive dielectric layer is greater than a thickness of the first bonding layer or a thickness of the second bonding layer.

20. The method of claim 17, further comprising:
before the depositing of the compressive dielectric layer over the frontside interconnect structure, depositing an etch stop layer over the frontside interconnect structure,
wherein the etch stop layer comprises silicon carbonitride.
